(19) United States
(12) Patent Application Publication
(10) Pub. No.: US 2019/0067489 A1
(43) Pub. Date: Feb. 28, 2019

(54) THIN FILM TRANSISTOR

(71) Applicant: Kabushiki Kaisha Kobe Seiko Sho (Kobe Steel, Ltd.), Kobe-shi (JP)

(72) Inventors: Hiroshi GOTO, Hyogo (JP); Mototaka OCHI, Hyogo (JP); Takumi KITAYAMA, Hyogo (JP); Toshihiro KUGIMIYA, Hyogo (JP)

(73) Assignee: Kabushiki Kaisha Kobe Seiko Sho (Kobe Steel, Ltd.), Kobe-shi (JP)

(21) Appl. No.: 16/090,996

(22) PCT Filed: Apr. 3, 2017
(86) PCT No.: PCT/JP2017/013984

§ 371 Date: Oct. 3, 2018

(30) Foreign Application Priority Data
Apr. 4, 2016 (JP) 2016-075375

(51) Int. Cl. H01L 29/786; H01L 29/24; H01L 29/49; H01L 21/02; H01L 21/443; H01L 21/477; H01L 29/66

(52) U.S. Cl. CPC H01L 29/78693; H01L 29/247; H01L 29/4908; H01L 29/78606; H01L 21/0217; H01L 29/66969; H01L 21/02565; H01L 21/02631; H01L 21/443; H01L 21/477; H01L 21/02271

(57) ABSTRACT

Disclosed herein is a thin film transistor including at least an oxide semiconductor layer, a gate insulting film, a gate electrode, a source-drain electrode and a protective film in this order on a substrate and further including a protective layer. The oxide semiconductor layer includes an oxide constituted of In, Ga, Sn and O and an atomic ratio of each metal element satisfies the following relationships:

0.30≤In/(In+Ga+Sn)≤0.50,

0.19≤Ga/(In+Ga+Sn)≤0.30 and

0.24≤Sn/(In+Ga+Sn)≤0.45.

The protective layer contains SiNx, and mobility is 35 cm²/Vs or more.

### TECHNICAL FIELD

The present invention relates to a thin film transistor containing an oxide semiconductor layer. More specifically, the invention relates to a thin film transistor suitable for use in a display device such as a liquid crystal display or an organic EL display as a top gate type thin film transistor.

### BACKGROUND ART

An amorphous oxide semiconductor has high carrier concentration as comparted with the conventional amorphous silicon thin film and is expected to apply to a next generation display requiring large size, high dissolution and high speed drive. Furthermore, the amorphous oxide semiconductor has large optical band gap and can be film-formed at low temperature. Therefore, the amorphous oxide semiconductor can be deposited on a resin substrate and is expected to apply to a lightweight and transparent display.

In-Ga-Zn (IGZO) amorphous oxide semiconductor comprising indium, gallium, zinc and oxide is well known as the amorphous oxide semiconductor as shown in, for example, Patent Documents 1 to 3.

The thin film transistor has two structures of a bottom gate type and a top gate type and is properly used depending on characteristics and properties thereof. The bottom gate type has the characteristic that mask number is small and production cost is reduced, and is mainly used in a thin film transistor using amorphous silicon.

On the other hand, the top gate type can prepare a fine transistor and has the characteristic that parasitic capacitance is small. Therefore, the top gate type is often used in a thin film transistor using polycrystal silicon. Thin film transistor structure optimum as a top gate type is applied even in an oxide semiconductor such that the performance is maximized by uses and properties.

### PRIOR ART DOCUMENT

### Patent Document

Patent Document 1: JP-A-2010-219538

Patent Document 2: JP-A-2011-174134

Patent Document 3: JP-A-2013-249537

### SUMMARY OF THE INVENTION

### Problems that the Invention is to Solve

However, field effect mobility (hereinafter sometimes referred to as “carrier mobility” or simply “mobility”) when a thin film transistor (TFT) has been prepared using the IGZO oxide semiconductor is 10 cm²/Vs or less, and a material having higher mobility is required in order to respond to large screen, high definition and high speed drive of a display device.

Furthermore, when hydrogen diffuses in an oxide semiconductor, carrier concentration changes, and when hydrogen excessively diffuses, the oxide semiconductor gets conductive. However, when hydrogen appropriately diffuses in high mobility oxide semiconductor, carrier mobility increases and the oxide semiconductor sometimes shows high mobility.

In view of the above circumstances, the present invention provides the optimum thin film transistor in order to use high mobility oxide semiconductor in a top gate type thin film transistor and maximize its performance.

### Means for Solving the Problems

The present inventors have found that the above problems can be solved by adopting a specific atom ratio of metal elements in an oxide semiconductor, a protective layer and a buffer layer and have reached to complete the present invention.

### Advantageous Effect of the Invention

Specifically, the present invention is as follows.

[1] A thin film transistor including at least an oxide semiconductor layer, a gate insulting film, a gate electrode, a source-drain electrode and a protective film in this order on a substrate and further including a protective layer,

wherein the oxide semiconductor layer includes an oxide constituted of In, Ga, Sn and O and an atomic ratio of each metal element satisfies the following relationships:

0.30≤In/(In+Ga+Sn)≤0.50,

0.19≤Ga/(In+Ga+Sn)≤0.30 and

0.24≤Sn/(In+Ga+Sn)≤0.45,

the protective layer contains SiNx, and

mobility is 35 cm²/Vs or more.

[2] The thin film transistor described in [1] above, wherein the atomic ratio of In and Ga in the oxide semiconductor layer satisfies the relationship:

0.60≤In/(In+Ga)≤0.70.

[3] The thin film transistor described in [1] or [2] above, wherein the gate insulating film includes SiOx and at least any one of SiNx and SiOyNz, and

the oxide semiconductor layer is in contact with the SiOx in the gate insulting film.

[4] The thin film transistor described in [3] above, wherein a ratio between a thickness of the SiOx and the total thickness of the at least any one of the SiNx and the SiOyNz in the gate insulating film is 1:1 to 1:4.

[5] A thin film transistor including at least a buffer layer, an oxide semiconductor layer, a gate insulating film, a gate electrode, a source-drain electrode and a protective film in this order on a substrate, and further including a protective layer,

wherein the oxide semiconductor layer includes an oxide constituted of In, Ga, Sn and O and an atomic ratio of each metal element satisfies the relationships:

0.30≤In/(In+Ga+Sn)≤0.50,

0.19≤Ga/(In+Ga+Sn)≤0.30 and

0.24≤Sn/(In+Ga+Sn)≤0.45,

the buffer layer contains at least any one of SiNx and SiOyNz,

the protective layer contains SiNx, and

mobility is 35 cm²/Vs or more.

According to the present invention, In-Ga-Zn-Sn oxide is used as an oxide semiconductor layer and a top gate type thin film transistor achieving high mobility can be obtained.

### BRIEF DESCRIPTION OF THE DRAWINGS

FIG. 1 is a schematic cross-sectional view of a top gate type thin film transistor according to the present invention.

FIG. 2 is a schematic cross-sectional view showing another embodiment of a top gate type thin film transistor according to the present invention.

### MODE FOR CARRYING OUT THE INVENTION

The thin film transistor according to the present invention has achieved high mobility of a oxide semiconductor layer by appropriately controlling an atomic ratio of respective metal elements and additionally interposing an insulating layer to be a hydrogen diffusion source such as SiNx and SiOyNz in an appropriate form in a thin film transistor structure when In-Ga-Sn oxide containing In, Ga and Sn as metal elements has is used in a semiconductor layer of a top gate type thin film transistor.

Specifically, the thin film transistor according to the present invention is a top gate type TFT including at least an oxide semiconductor layer, a gate insulating film, a gate electrode, a source-drain electrode and a protective film in this order on a substrate and further including a protective layer,

wherein the oxide semiconductor layer includes an oxide constituted of In, Ga, Sn, and O and an atomic ratio of each metal element satisfies the following relationships:

0.30≤In/(In+Ga+Sn)≤0.50,

0.19≤Ga/(In+Ga+Sn)≤0.30 and

0.24≤Sn/(In+Ga+Sn)≤0.45, and

the protective layer contains SiNx.

The thin film transistor according to the present invention can have a high mobility of 35 cm²/Vs or more by having the above constitution and conducting a post-annealing treatment.

The term “protective film” in the present description is a film to protect a source-drain electrode and means a film called a passivation film, a final protective film or the like.

Furthermore, the term “protective layer” is a layer called a protection layer or the like and is a layer for, for example, protecting TFT from an etching solution.

As another embodiment according to the present invention, the thin film transistor may have a buffer layer between the substrate and the oxide semiconductor layer. That is, the thin film transistor may include at least a buffer layer, an oxide semiconductor layer, a gate insulating film, a gate electrode, a source-drain electrode and a protective film in this order on a substrate. In this case, the buffer layer contains at least any one of SiNx and SiOyNz.

### Oxide Semiconductor Layer

The oxide semiconductor layer in the present invention includes an oxide constituted of In, Ga, Sn and O, and an atomic ratio of each metal element to the total of In, Ga and Sn satisfies the following relational formulae,

0.30≤In/(In+Ga+Sn)≤0.50

0.19≤Ga/(In+Ga+Sn)≤0.30 and

0.24≤Sn/(In+Ga+Sn)≤0.45.

Of the metal elements, In is an element contributing to the improvement of electrical conductivity.

The conductivity of the oxide semiconductor layer is improved as In atomic ratio is increased, that is, In amount occupied in the metal elements is increased. Therefore, field effect mobility is increased. The In atomic ratio must be 0.30 or more in order to effectively exhibit the above action. The In atomic ratio is preferably 0.31 or more, more preferably 0.35 or more, and still more preferably 0.40 or more.

On the other hand, when the In atomic ratio is too large, carrier density excessively increases and threshold voltage is sometimes decreased to a negative voltage. For this reason, an upper limit of the In atomic ratio is 0.50 or less, preferably 0.48 or less, and more preferably 0.45 or less.

Ga is an element contributing to the reduction of oxygen deficiency and the control of carrier density.

Electrical stability of the oxide semiconductor layer is improved and the effect of suppressing excessive generation of a carrier is exhibited, as Ga atomic ratio is increased. The Ga atomic ratio must be 0.19 or more in order to effectively exhibit the above action. The Ga atomic ratio is preferably 0.22 or more and more preferably 0.25 or more.

On the other hand, when the Ga atomic ratio is too large, conductivity of the oxide semiconductor layer is decreased and field effect mobility is liable to be decreased. For this reason, an upper limit of the Ga atomic ratio is 0.30 or less and preferably 0.28 or less.

Sn is an element contributing to the improvement of acid etching resistance.

Resistance to an inorganic acid etching liquid in the oxide semiconductor layer is improved as the Sn atomic ratio is increased. The Sn atomic ratio must be 0.24 or more in order to effectively exhibit those actions. The Sn atomic ratio is preferably 0.30 or more, more preferably 0.31 or more, and still more preferably 0.35 or more.

On the other hand, when the Sn atomic ratio is too large, field effect mobility of the oxide semiconductor layer is decreased and additionally the resistance to the acid etching liquid is increased more than necessary, making it difficult to process the oxide semiconductor layer film itself. For this reason, an upper limit of the Sn atomic ratio is 0.45 or less, preferably 0.40 or less and more preferably 0.38 or less.

The composition of the oxide semiconductor layer preferably satisfies the following formula in terms of a metal element ratio of In and Ga:

0.60≤In/(In+Ga)≤0.70.

When the added amount of In is increased, carrier density is increased, but defects are increased and reliability is deteriorated. Therefore, Ga is added to balance, thereby making it possible to control carrier density and defects, and the oxide semiconductor layer having high reliability can be obtained. To achieve this, the above relational formula is preferably satisfied.

The “reliability” used herein means NBTIS test in which negative bias and temperature stress have been added while irradiating light from a glass side of a thin film transistor, and it can be said that reliability is high as a shift amount (ΔVth) of a threshold voltage is small.

The thin film transistor including the oxide semiconductor layer according to the present invention shows high mobility of 35 cm²/Vs or more, preferably 40 cm²/Vs or more, and more preferably 50 cm²/Vs or more. The mobility of the thin film transistor using In-Ga-Zn-O (IGZO) conventionally used is about 10 cm²/Vs. Thus, the mobility is greatly increased in the present invention.

Drain current flowing between source-drain electrodes is also increased because the oxide semiconductor layer in the present invention high carrier concentration as compared with IGZO.

High mobility of the oxide semiconductor layer in the present invention is related to hydrogen and hydrogen compound diffusing in the oxide semiconductor layer from the protective layer, preferably from the protective layer through silicon oxide SiOx in contact with the oxide semiconductor layer, by a heat treatment.

In other words, when hydrogen and hydrogen compound diffuse in the oxide semiconductor layer, carrier density of the oxide semiconductor layer is increased. Hydrogen and hydrogen compound contained in SiNx constituting the protective layer diffuse in the oxide semiconductor layer when a heat treatment of 200° C. or higher (post-annealing treatment) is added.

In the thin film transistor including the buffer layer between the substrate and the oxide semiconductor layer, high mobility of the oxide semiconductor layer is related to hydrogen and hydrogen compound diffusing in the oxide semiconductor layer from the buffer layer in contact with the oxide semiconductor layer. Hydrogen and hydrogen compound contained in at least any one of SiNx and SiOyNz constituting the buffer layer diffuse in the oxide semiconductor layer.

### Protective Layer, Gate Insulating Film and Buffer Layer

The protective layer in the present invention contains SiNx. The protective layer may be a single film and may be a laminated film so long as SiNx is contained. From the standpoint of the risk of the oxide semiconductor being conductive by excessive hydrogen diffusion, a laminated film having a silicon oxide film formed on the side in contact with the oxide semiconductor is preferred.

For the protective layer, use of SiNx film formed using CVD (chemical vapor deposition) method is preferred. The SiNx film deposited by CVD method contains hydrogen in high concentration of about 25 atom %. The hydrogen contained in the protective layer diffuses in the oxide semiconductor layer by thermal history (post-annealing treatment) added during the step of thin film transistor formation and the oxide semiconductor layer changes into a layer having high carrier mobility.

Diffusion source of hydrogen may be a gate insulating film. In other words, the gate insulating film in conjunction with the protective layer may be a film containing SiNx. The film containing SiNx is not limited to an SiNx film single layer but may be a laminated film. Furthermore, as with the SiNx, a film containing SiOyNz containing hydrogen may be used.

When the protective layer or the gate insulating film is an SiNx film single layer, hydrogen excessively diffuses in the oxide semiconductor layer. Therefore, when an SiOx film having small hydrogen content is deposited on the oxide semiconductor layer and an SiNx film is successively deposited thereon, excessive hydrogen diffusion in the oxide semiconductor layer can be suppressed, and this is more preferred.

Specifically, the gate insulating film preferably contains SiOx and at least any one of SiNx and SiOyNz. Examples of the gate insulating film include a laminated film of an SiOx single film and a single layer of SiNx or SiOyNz and a laminated film of an SiOx single film, an SiNx single film and a SiOyNz single film. Above all, a laminated film of an SiOx single film and an SiNx single film or an SiOyNz single film is preferred from the standpoint of costs.

In the gate insulating film, the ratio of the thickness of SiOx to the total thickness of at least any one of SiNx and SiOyNz is preferably 1:1 to 1:4 from the standpoint of avoiding being conductive by excessive hydrogen diffusion. The ratio is more preferably 1:1 to 1:2. The thickness of SiOx and the total thickness of at least any one of SiNx and SiOyNz can be measured by an ellipsometer.

The structure capable of diffusing hydrogen as with those includes the case where the buffer layer is included between a substrate and the oxide semiconductor layer. In other words, when the buffer layer is included, the buffer layer contains at least any one of SiNx and SiOyNz. In this case, the protective layer and gate insulating film may contain or may not contain SiNx, but the protective film more preferably contains SiNx.

The buffer layer may be a single film and may be a laminated film.

As with the protective layer, the buffer layer is effectively formed by CVD method. The buffer layer contains at least any one of SiNx and SiOyNz. Thus, hydrogen diffusion in the oxide semiconductor layer from the buffer layer is similarly expected.

In this case, hydrogen can be suppressed from excessively diffusing in the oxide semiconductor layer by further inserting (depositing) an SiOx film having small amount of hydrogen on the interface in contact with the oxide semiconductor layer, and this is more preferred.

### Gate Electrode, Source-Drain Electrode and Protective Film

As the gate electrode, source-drain electrode and protective film in the thin film transistor according to the present invention, the conventional electrodes and films, can be used respectively.

Specifically, as the gate electrode, a metal having low electrical resistivity such as Al or Cu, a high melting metal having high heat resistance such as Mo, Cr or Ti, or alloys thereof can be preferably used.

Examples of the source-drain electrode include interconnection layers containing Mo, Al, Cu, Ti, Ta, W, Nb and alloys thereof. The electrode can be formed by, for example, depositing a metal thin film by a magnetron sputtering method or the like, patterning by photolithography and performing wet etching.

The protective film may be any film so long as it can protect the source-drain electrode, and examples thereof include a silicon nitride film, a silicon oxide film, a silicon oxynitride film, BPSG and PSG.

### Formation Method of Thin Film Transistor

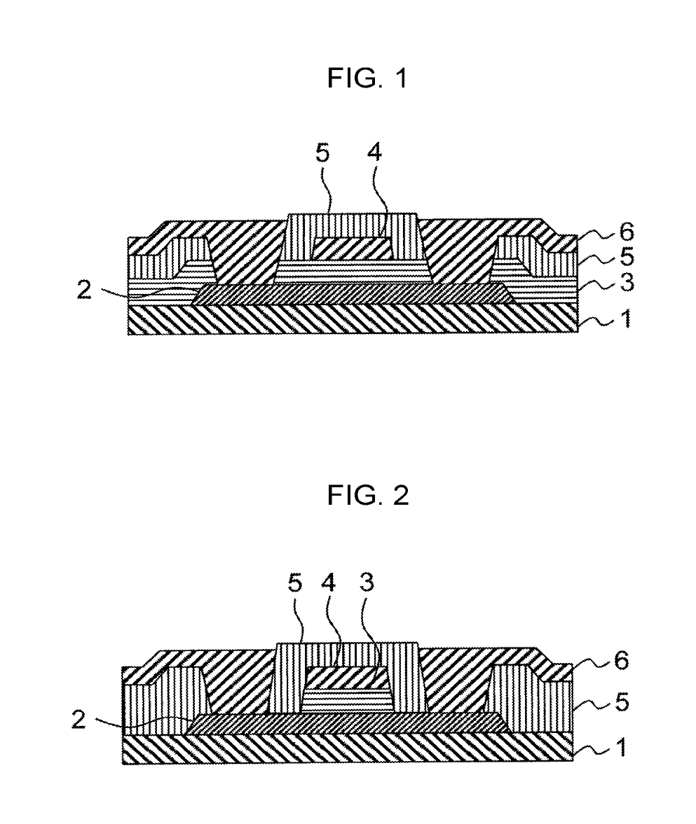

The thin film transistor according to the present invention is a top gate type, the representative schematic cross-sectional view thereof is shown in FIG. 1 and one example of the formation method is described below. However, the invention is not construed as being limited to those.

An oxide semiconductor layer 2 is formed on a substrate 1. Examples of the substrate include a glass substrate, a silicon substrate and a heat-resistant resin film. The oxide semiconductor layer is formed on the substrate using a sputtering process or the like.

The composition of the oxide semiconductor layer can be regarded to be the same composition as the composition of a sputtering target, but can be measured by ICP emission spectroscopy.

Film thickness of the oxide semiconductor layer is preferably 30 to 100 nm from the standpoint of properties of a thin film transistor, and more preferably 40 to 50 nm. The thickness of the oxide semiconductor layer can be measured by a step profiler.

Sputtering conditions are not particularly limited, but a gas pressure is preferably controlled to a range of 1 to 5 mTorr. When the gas pressure is less than 1 mTorr, a film density is sometimes insufficient, and when the gas pressure exceeds 5 mTorr, sufficient film quality such that reliability of TFT is obtained is sometimes not obtained. The gas pressure is more preferably 2 mTorr or more. On the other hand, the gas pressure is more preferably 4 mTorr or less and still more preferably 3 mTorr or less.

A buffer layer (not shown) may be formed by CVD method or the like before deposition of the oxide semiconductor layer. When TFT includes a protective layer containing SiNx, as the buffer layer SiOx, SiNx, SiOyNz and the like can be used. Above all, the buffer layer preferably contains at least any one of SiNx and SiOyNz. Preferred examples of the buffer layer include a laminated film of SiOx film and SiNx film and a laminated film of SiOx film and SiOyNz film.

After forming the oxide semiconductor layer, a heat treatment is conducted and deposition of a gate insulating film 3 is conducted. As the heat treatment conditions, the atmosphere is preferably air atmosphere or steam atmosphere. The heat treatment temperature is preferably 350 to 450° C. from the standpoint of the improvement of film quality, and more preferably 380 to 400° C. The heat treatment time is preferably 30 minutes to 2 hours from the standpoint of the improvement of film quality, and more preferably 30 minutes to 1 hour.

The gate insulating film is preferably deposited by CVD method. The gate insulating film is preferably a laminated film of SiOx film and SiNx film and a laminated film of SiOx film and SiOyNz film.

After forming a gate electrode 4, a layer containing SiNx is deposited as a protective layer 5 by CVD method or the like, and a through-hole is formed.

The through-hole is formed by forming a through-hole pattern by photolithography or the like and forming the through-hole by RIE plasma etching apparatus or the like.

Thereafter, a source-drain electrode 6 is formed by photolithography and wet etching or the like, a protective film (not shown) is finally formed and a heat treatment (post-annealing treatment) is then conducted.

In the heat treatment, heat treatment conditions are appropriately set such that desired film quality of the oxide semiconductor layer is obtained. For example, the heat treatment temperature is preferably 200 to 300° C. from the standpoint of the suppression of electron trap in the interface between the oxide semiconductor and the protective layer, and more preferably 250 to 290° C. The heat treatment time is preferably 30 to 90 minutes from the standpoint of the trap suppression, and more preferably 30 to 60 minutes. The atmosphere is not particularly limited, and examples thereof include nitrogen atmosphere and air atmosphere. When the post-annealing treatment is not conducted, hydrogen and hydrogen compound contained in SiNx constituting the protective layer do not diffuse into the oxide semiconductor layer. Thus, the oxide semiconductor layer free of the post-annealing treatment differs from the oxide semiconductor layer of the present invention, and mobility of a thin film transistor to be obtained is low. Thus, such a thin film transistor obtained differs from the thin film transistor according to the present invention.

Schematic cross-sectional view in another embodiment of the top gate type thin film transistor according to the present invention is shown in FIG. 2.

In the thin film transistor shown in FIG. 2, after forming the gate electrode 4, plasma etching is continuously conducted from the upper of the gate electrode 4, only the gate insulating film 3 just below the gate electrode is remained and others are removed. A film containing SiNx is deposited as the protective layer 5, a through-hole is formed in the protective layer and a source-drain electrode 6 is formed. After forming the protective film, the heat treatment is conducted. Thus, high mobility thin film transistor can be obtained.

In other words, the thin film transistor according to the present invention is a top gate type and achieves high mobility by including the oxide semiconductor layer having specific composition and the protective layer containing SiNx.

According to the investigation results by the present inventors, it has been clarified that due to the characteristics described above, hydrogen contained in the protective layer is diffused in the oxide semiconductor layer, thereby greatly contributing to the development of high mobility. The mobility improvement action is first obtained by using TFT according to the present invention, and the action does not occur when, for example, the IGZO oxide semiconductor layer described in Patent Document 1 described before has been used, as demonstrated in the later described

It is considered that not only SiNx is contained in the protective layer but SiNx layer is interposed in a part of the gate insulating film and buffer layer in order to effectively increase carrier concentration in a channel region of the thin film transistor. However, excessive hydrogen diffusion makes the oxide semiconductor layer conductive, and care is necessary.

The amount of hydrogen contained in SiNx varies depending on amounts of silane and ammonia used in deposition and deposition conditions such as deposition temperature and deposition power. High reliability is generally required in a gate insulating film. Therefore, deposition is conducted at high temperature of 320 to 350° C. and the hydrogen content is small as 8 atom % or less. However, high hydrogen content of about 25 atom % can be achieved in the protective layer by decreasing the temperature and changing the proportion of a gas.

The thin film transistor shown in FIG. 2 has the characteristic that SiNx (protective layer 5) is close to the vicinity of a channel as compared with the thin film transistor shown in FIG. 1. In this structure, hydrogen from SiNx is easy to diffuse up to the vicinity of the channel.

For example, when the hydrogen content in SiNx is increased or the heat treatment temperature after formation of the protective layer is increased to 300° C. or higher, larger amount of hydrogen is poured into the oxide semiconductor, the oxide semiconductor layer in a region in contact with SiNx of the protective layer has excessive carrier concentration, and easily becomes conductive.

In top gate type TFT, even though gate voltage is applied, channel is not formed in the oxide semiconductor layer present between a channel formed just under the gate electrode of the oxide semiconductor layer and the source-drain electrode, and the oxide semiconductor layer is merely a resistive layer and inhibits the flow of drain current. For this reason, after etching the gate insulating film using the gate electrode as a mask, carriers are continuously generated by inducing defects of the surface of the oxide semiconductor layer by plasma irradiation, laser irradiation, treatment with medical liquid, or the like and the resistance of the oxide semiconductor on the part other than the channel is sometimes decreased.

On the other hand, in the case of the top gate type thin film transistor using the oxide semiconductor layer in the present invention, when deposition conditions and heat treatment conditions are adjusted such that hydrogen of SiNx of the protective layer is excessively poured into the oxide semiconductor layer, the oxide semiconductor layer other than the channel can be easily conductive. As a result, drain current is further easy to flow and high mobility is easy to obtain.

The top gate type thin film transistor of the present invention thus obtained can have high mobility of 35 cm²/Vs or more and preferably 40 cm²/Vs or more as shown in Table 1 described hereinafter.

### EXAMPLE

The present invention is further specifically described below by reference to Examples and Comparative Examples, but the invention is not construed as being limited those Examples.

### Test Example

The thin film transistor according to the present invention was prepared by the following procedures.

Ga-In-Sn-O film was deposited as an oxide semiconductor layer (film thickness: 100 nm) on a glass substrate (EAGLE XG manufactured by Corning Incorporated, diameter 101.6 mm×thickness 0.7 mm) so as to be an atomic ratio (Ga:In:Sn) shown in Table 1. Sputtering target having the same ratio of metal elements was used in deposition and the deposition was conducted using DC sputtering method. In Test Examples 4, 5 and 7, a buffer layer of a laminated film of silicon oxide film (SiOx film) and silicon nitride film (SiNx film) was formed on the glass substrate by CVD method before depositing the oxide semiconductor layer.

An apparatus used in the sputtering is CS-200 manufactured by ULVAC, Inc., and the sputtering conditions are as follows.

### Sputtering Conditions

Substrate temperature: room temperature

Deposition power: DC 200 W

Gas pressure: 1 mTorr

Oxygen partial pressure: 100×O₂/(Ar+O₂)=4%

Heat treatment was conducted at 350° C. for 1 hour in the air atmosphere and a gate insulating film that is a silicon oxide film (SiOx film) or a laminated film of silicon oxide film (SiOx film) and silicon nitride film (SiNx film) was continuously deposited using a plasma CVD apparatus. A gate electrode (film thickness 250 nm) was formed and a protective layer containing SiNx was deposited by CVD method. In Test Examples 3 to 5, a protective film containing SiOx was formed.

Regarding the plasma CVD method in the deposition of the gate insulating film, in the case of the deposition of SiOx film, the SiOx film was deposited under the conditions of carrier gas: mixed gas of SiH₄ and N₂O, deposition power: 300 W and deposition temperature: 350° C. In the case of the deposition of SiNx film, the SiNx film was deposited under the condition of carrier gas: mixed gas of SiH₄, N₂ and NH₃, deposition power: 300 W and deposition temperature: 320° C.

The gate electrode was deposited using pure Mo sputtering target under the conditions of deposition temperature: room temperature, deposition power: 300 W, carrier gas: Ar and gas pressure: 2 mTorr by DC sputtering method.

Regarding the CVD method in the protective layer, in the case of the deposition of SiOx film, the SiOx film was deposited under the conditions of carrier gas: deposition mixed gas of SiH_{4,} and N₂O, deposition power: 300 W and deposition temperature: 200° C. In the case of the deposition of SiNx film, the SiN film was deposited under the conditions of carrier gas: mixed gas of SiH₄, N₂ and NH₃, deposition power: 300 W and deposition temperature: 200° C.

Through-hole pattern was formed by photolithography, a through-hole was formed in the silicon oxide film by RIE plasma etching apparatus, Mo electrode having a film thickness of 100 nm was deposited, and a source-drain electrode was formed by photolithography and wet etching by phosphoric acetic and nitric acids. The SiNx film was formed using a plasma CVD and the protective film was formed under the conditions of carrier gas: mixed gas of SiH₄, N₂ and NH₃, deposition power: 300 W and deposition temperature: 150° C., then a heat treatment (post-annealing treatment) was finally conducted at 250° C. for 30 minutes in nitrogen atmosphere. The post-annealing treatment was not conducted in some test examples.

In the wet etching, “ITO-07N” manufactured by Kanto Chemical Co., Inc. was used, and liquid temperature was room temperature.

### Evaluation Method

### Hydrogen Content

Hydrogen content in the protective layer, gate insulating film and buffer layer obtained was measured with high resolution ERDA (High Resolution-Elastic Recoil Detection Analysis: HR-ERDA). The apparatus is high resolution RBS analyzer HRBS500 manufactured by Kobe Steel Co., Ltd., and measurement conditions are shown below.

### Measurement Conditions

Energy of incident ion: 480 keV

Ion species: N⁺

Scattering angle: 30°

Incident angle: 70° to normal line of sample surface

Sample current: about 2 nA

Dose: about 0.4 μC

N+ ions having energy of 480 keV were entered at an angle of 70° to a normal line of a sample surface and recoil hydrogen ions were measured by a deflecting magnetic field energy analyzer at a position of 30° of a scattering angle. The dose was obtained by vibrating a pendulum in a beam path and measuring current amount irradiated to the pendulum. The hydrogen content was calculated by converting the channel of a horizontal axis into energy of recoil ions on the basis of the middle point at high energy side edge of hydrogen signal and deducting system background.

### Mobility

Mobility of the thin film transistor obtained was measured. An apparatus used in the measurement of mobility is a manual prober and Keithley 4200-SCS of a semiconductor parameter analyzer, and measurement conditions are shown below.

### Measurement Conditions

Gate voltage: −30 to 30V (0.25V step)

Drain voltage: +10V

Field effect mobility μ_{FE} was derived in a saturated region of Vg>Vd−Vth from TFT properties. In the saturated region, Vg was gate voltage, Vd was drain voltage, Id was drain current, L and W were channel length and channel width of TFT chip, respectively, Ci was electrostatic capacity of a gate insulating film and μ_{FE} was field effect mobility.

The μ_{FE} is derived from the formula below. In the present Examples, the field effect mobility μ_{FE} was derived from the inclination of drain current-gate voltage properties (Id-Vg properties) in the vicinity of gate voltage satisfying a linear region. In the present Examples, the field effect mobility μ_{FE} after a stress application test described hereinafter was described as “Mobility” in Table 1. In Table 1, “Conductive” in the column of “Mobility” means the state that the thin film transistor does not show off-state.

$${μ}_{FE} = \frac{\partial {I}_{d}}{\partial {V}_{g}} ( \frac{L}{{C}_{i} W ( {V}_{g} - {V}_{th} )} ) \qquad [ Math . 1 ]$$

### NBTIS

Reliability of the thin film transistor obtained was evaluated by NBTIS test in which negative bias and temperature stress had been added while irradiating light from a glass substrate side of the thin film transistor. The measurement conditions are shown below. It says that reliability is high as a shift amount (ΔVth) of a threshold voltage is small.

An apparatus used in the NBTIS method is a manual prober and Keithley 4200-SCS of a semiconductor parameter analyzer, and measurement conditions are shown below.

### Measurement Conditions

Gate voltage: −20V

Drain voltage: +10V

Substrate stage temperature: 60° C.

Light irradiation condition: Irradiating white LED from the back of a substrate (glass substrate) in 25000 nit for 2 hours.

The results of the NBTIS test are shown in Table 1. The mark “ο” means that a shift amount of a threshold voltage (gate voltage when drain current exceeded 1 nA) before and after the test was 5V or less, the mark “×” means that the shift amount exceeded 5V and the mark “−” means that the test was not conducted.

### Etching Processability

Etching processability of the thin film transistor obtained was evaluated by measuring thickness loss in the etching processing by a step profiler. The step profiler used was α step. The thin film transistor was dipped in an etching liquid in the state of masking with Kapton tape, the Kapton tape was then peeled to form steps, and steps were measured by scanning stylus (needle).

The test results of the etching processing are shown in the column of “Etching” in Table 1. The mark “◯” means that etching processing was possible (thickness loss was observed) and the mark “×” means that etching processing was impossible (thickness loss was not observed).

In the column of “Comprehensive evaluation” in Table 1, the mark “◯” means that all properties are satisfied and the mark “×” means that least one of properties is not satisfied.

TABLE 1

| | | | | | Protective layer | | Gate insulating film | | |
|---|---|---|---|---|---|---|---|---|---|
| Test | Atomic ratio (%) | | | | | Thickness | | Thickness | Buffer |
| Ex. | In | Ga | Sn | Ga/In + Ga | Composition | (nm) | Composition | (nm) | layer |
| 1 | 49.8 | 25.3 | 24.9 | 0.66 | SiNx/SiOx | 150/100 | SiOx | 250 | — |
| 2 | | | | | SiNx/SiOx | 150/100 | SiOx | 250 | — |
| 3 | | | | | SiOx | 250 | SiOx/SiNx | 100/150 | — |
| 4 | | | | | SiOx | 250 | SiOx | 250 | SiOx/SiNx |
| 5 | | | | | SiOx | 250 | SiOx | 250 | SiOx/SiNx |
| 6 | | | | | SiNx/SiOx | 150/100 | SiOx/SiNx | 100/150 | — |
| 7 | | | | | SiNx/SiOx | 150/100 | SiOx/SiNx | 100/150 | SiOx/SiNx |
| 8 | 45.5 | 29.2 | 25.3 | 0.61 | SiNx/SiOx | 150/100 | SiOx | 250 | — |
| 9 | | | | | SiNx/SiOx | 150/100 | SiOx | 250 | — |
| 10 | 40.1 | 30.9 | 29 | 0.56 | SiNx/SiOx | 150/100 | SiOx | 250 | — |
| 11 | | | | | SiNx/SiOx | 150/100 | SiOx | 250 | — |
| 12 | 25 | 45.5 | 29.5 | 0.35 | SiNx/SiOx | 150/100 | SiOx | 250 | — |
| 13 | | | | | SiNx/SiOx | 150/100 | SiOx | 250 | — |
| 14 | 40.7 | 19.2 | 40.1 | 0.68 | SiNx/SiOx | 150/100 | SiOx | 250 | — |
| 15 | | | | | SiNx/SiOx | 150/100 | SiOx | 250 | — |
| 16 | 31.3 | 29.4 | 39.3 | 0.52 | SiNx/SiOx | 150/100 | SiOx | 250 | — |
| 17 | | | | | SiNx/SiOx | 150/100 | SiOx | 250 | — |
| 18 | 49.9 | 20.3 | 29.8 | 0.71 | SiNx/SiOx | 150/100 | SiOx | 250 | — |
| 19 | | | | | SiNx/SiOx | 150/100 | SiOx | 250 | — |
| 20 | 24.4 | 31.2 | 44.4 | 0.44 | SiNx/SiOx | 150/100 | SiOx | 250 | — |
| 21 | | | | | SiNx/SiOx | 150/100 | SiOx | 250 | — |
| 22 | 54.6 | 20.2 | 25.2 | 0.73 | SiNx/SiOx | 150/100 | SiOx | 250 | — |
| 23 | | | | | SiNx/SiOx | 150/100 | SiOx | 250 | — |

| | Hydrogen content of SiNx | | | | | | | |
|---|---|---|---|---|---|---|---|---|
| | | Gate | | Post- | | | Etching | |
| Test | Protective | insulating | Buffer | annealing | | | Process- | Comprehensive |
| Ex. | layer | film | layer | temperature | Mobility | NBTIS | ability | evaluation |
| 1 | 25 atom % | — | — | None | 18.1 | — | ◯ | X |
| 2 | 25 atom % | — | — | 250° C. | 70.1 | ◯ | | ◯ |
| 3 | — | 8 atom % | — | 250° C. | 49.9 | ◯ | | ◯ |
| 4 | — | — | 8 atom % | 250° C. | 41.3 | ◯ | | ◯ |
| 5 | — | — | 25 atom % | 250° C. | conductive | X | | X |
| 6 | 25 atom % | 8 atom % | — | 250° C. | 55.8 | ◯ | | ◯ |
| 7 | 25 atom % | 8 atom % | 8 atom % | 250° C. | 56.3 | ◯ | | ◯ |
| 8 | 25 atom % | — | — | None | 14.6 | — | ◯ | X |
| 9 | 25 atom % | — | — | 250° C. | 52.3 | ◯ | | ◯ |
| 10 | 25 atom % | — | — | None | 15.4 | — | ◯ | X |
| 11 | 25 atom % | — | — | 250° C. | 19.7 | ◯ | | X |
| 12 | 25 atom % | — | — | None | 11.9 | — | ◯ | X |
| 13 | 25 atom % | — | — | 250° C. | 12.1 | ◯ | | X |
| 14 | 25 atom % | — | — | None | 12.6 | — | X | X |
| 15 | 25 atom % | — | — | 250° C. | 45.5 | ◯ | | X |
| 16 | 25 atom % | — | — | None | 12.1 | — | X | X |
| 17 | 25 atom % | — | — | 250° C. | 36.2 | ◯ | | X |
| 18 | 25 atom % | — | — | None | 17.5 | — | ◯ | X |
| 19 | 25 atom % | — | — | 250° C. | 74.3 | ◯ | | ◯ |
| 20 | 25 atom % | — | — | None | 11.9 | — | X | X |
| 21 | 25 atom % | — | — | 250° C. | 41.7 | X | | X |
| 22 | 25 atom % | — | — | None | 19 | — | X | X |
| 23 | 25 atom % | — | — | 250° C. | 49.1 | X | | X |

While the present invention has been described in detail and with reference to specific embodiments thereof, it will be apparent to one skilled in the art that various changes and modifications can be made therein without departing from the spirit and scope thereof.

This application is based on Japanese Patent Application No. 2016-075375 filed on Apr. 4, 2016, the entire subject matter of which is incorporated herein by reference.

### INDUSTRIAL APPLICABILITY

The present invention increases mobility of a top gate type thin film transistor and is useful in a display device such as a liquid crystal display or an organic EL display.

### DESCRIPTION OF REFERENCE NUMERALS AND SIGNS

1 Substrate

2 Oxide semiconductor layer

3 Gate insulating film

4 Gate electrode

5 Protective layer

6 Source-drain electrode

1. A thin film transistor, comprising an oxide semiconductor layer, a gate insulting film, a gate electrode, a source-drain electrode and a protective film in this order on a substrate and further comprising a protective layer,
wherein:
the oxide semiconductor layer comprises an oxide constituted of In, Ga, Sn and O and an atomic ratio of each metal element satisfies the following relationships:
0.30≤In/(In+Ga+Sn)≤0.50,
0.19≤Ga/(In+Ga+Sn)≤0.30, and
0.24≤Sn/(In+Ga+Sn)≤0.45;
the protective layer comprises SiNx; and
a mobility of the thin film transistor is 35 cm²/Vs or more.

2. The thin film transistor according to claim 1, wherein the atomic ratio of In and Ga in the oxide semiconductor layer satisfies the relationship:
0.60≤In/(In+Ga)≤0.70.

3. The thin film transistor according to claim 1, wherein:
the gate insulating film comprises SiOx and at least one of SiNx and SiOyNz; and
the oxide semiconductor layer is in contact with the SiOx in the gate insulting film.

4. The thin film transistor according to claim 3, wherein a ratio between a thickness of the SiOx and a total thickness of the at least one of the SiNx and the SiOyNz in the gate insulating film is 1:1 to 1:4.

5. A thin film transistor, comprising a buffer layer, an oxide semiconductor layer, a gate insulating film, a gate electrode, a source-drain electrode and a protective film in this order on a substrate, and further comprising a protective layer,
wherein:
the oxide semiconductor layer comprises an oxide constituted of In, Ga, Sn and O and an atomic ratio of each metal element satisfies the relationships:
0.30≤In/(In+Ga+Sn)≤0.50
0.19≤Ga/(In+Ga+Sn)≤0.30, and
0.24≤Sn/(In+Ga+Sn)≤0.45;
the buffer layer comprises at least one of SiNx and SiOyNz,
the protective layer comprises SiNx, and
a mobility of the thin film transistor is 35 cm²/Vs or more.

6. The thin film transistor according to claim 2, wherein:
the gate insulating film comprises SiOx and at least any one of SiNx and SiOyNz; and
the oxide semiconductor layer is in contact with the SiOx in the gate insulting film.

7. The thin film transistor according to claim 6, wherein a ratio between a thickness of the SiOx and a total thickness of the at least any one of the SiNx and the SiOyNz in the gate insulating film is 1:1 to 1:4.
